(19) United States
(12) Patent Application Publication
(10) Pub. No.: US 2006/0275925 A1
(43) Pub. Date: Dec. 7, 2006

(54) Electrical substrate for use as a carrier of biomolecules

(76) Inventors: Gerhard Hartwich, Munich (DE); Harald Lossau, Mannheim (DE); Herbert Wieder, Mannheim (DE); Norbert Persike, Munich (DE); Christian Musewald, Toging am Inn (DE)

Correspondence Address: CROCKETT & CROCKETT, 24012 CALLE DE LA PLATA, SUITE 400, LAGUNA HILLS, CA, 92653, US

(21) Appl. No.: 10/539,463

(22) PCT Filed: Dec. 23, 2003
(86) PCT No.: PCT/DE03/04259

§ 371 Date: Jul. 26, 2006

(30) Foreign Application Priority Data
Dec. 23, 2002 (DE) 102 61 528.4

(51) Int. Cl. H01L 21/00

(52) U.S. Cl. 438/1

(57) ABSTRACT

An electrical substrate for use as a carrier of biomolecules in a method for electrochemical detection in an electrolyte solution exhibits an insulating support plate (12) bearing a conductive pattern (20; 20A-20C, 28) having conductor paths (20; 20A-20C) and connecting contact surfaces, and, disposed on the conductor paths (20; 20A-20C), test sites (24) for the application of biomolecules (26), the conductor paths (20; 20A-20C) exhibiting a metal core (14) made of a highly conductive base metal and an external gold layer (18), and the conductor paths (20; 20A-20C) being provided with a diffusion barrier layer (16) that prevents direct contact of the electrolyte solution with the metal core (14) during the electrochemical detection method.

### FIELD OF THE INVENTION

The present invention relates to an electrical substrate for use as a carrier of biomolecules in a method for electrochemical detection in an electrolyte solution. The present invention also relates to the use of such a substrate in an electrochemical method for detecting biomolecules.

### BACKGROUND OF THE INVENTION

The detection of substances contained in an electrolyte solution is described, for example, in DE 199 56 729 C1. In the method known as “high pressure liquid chromatography” (HPLC), a tracer substance is added to a carrier liquid and the electrolyte solution created is passed through a separation column. The separation column exhibits a varyingly intense retention effect with respect to various tracer substances, so that the various substances arrive at the exit of the column at different times and can be analyzed individually.

For analysis, behind the separation column is disposed a measuring cell having a flow-through chamber into which a working electrode and a counterelectrode protrude, over which the electrolyte solution flows. To detect a tracer substance, between the working electrode and the counterelectrode is applied a potential that oxidizes or reduces the tracer substance. The electron flow is measured as a current flow at the working electrode and is a measure of the content of the tracer substance in the sample.

In addition to such serial methods, increasingly, parallel detection methods by means of array technology using so-called DNA or protein chips are being applied. Here, for example for genetic analysis, a library of known DNA sequences, of the probe oligonucleotides, is fixed in an ordered grid on a chip on a surface so that the position of each individual DNA sequence is known. If fragments of active genes, of the target oligonucleotides whose sequences are complementary to certain probe oligonucleotides on the chip, exist in the test solution, the target oligonucleotides can be identified and read out by detecting the corresponding hybridization events on the chip.

The known use of radioactive labels in DNA/RNA sequencing exhibits a number of disadvantages, such as the elaborate safety precautions in dealing with radioactive materials. In the known methods with fluorescence or mass spectrometric detection, the costs of equipment provision are very high.

To counter these disadvantages, it has been suggested to detect the association events using the change in the electrochemical properties of the probe oligonucleotide, entailed by the association, compare e.g. WO 97/46568, WO 99/51778, WO 00/31101 or WO 00/42217.

### DESCRIPTION OF THE INVENTION

This is where the present invention begins. The object of the present invention, as characterized in the claims, is to increase the detection accuracy of an electrochemical detection method of the kind cited above.

According to the present invention, this object is solved by the electrical substrate according to claim 1 and the use according to claim 26. Further advantageous details, aspects and embodiments of the present invention are evident from the dependent claims, the description, the figures and the examples.

The electrical substrate according to the present invention includes an insulating support plate bearing a conductive pattern having conductor paths and connecting contact surfaces and, disposed on the conductor paths, test sites for the application of biomolecules. Here, the conductor paths exhibit a metal core made of a highly conductive base metal and a gold layer surrounding the metal core. Furthermore, the conductor paths are provided continuously with a diffusion barrier layer that prevents direct contact of the electrolyte solution with the metal core when executing an electrochemical detection method.

The present invention rests on the findings of the current inventors that the base metal core, typically copper, provided on electrical substrates can strongly influence the test signal during electrochemical detection. Thus, for example, the copper oxidation causes a signal peak at a potential of 250 mV relative to an Ag/AgCl reference electrode. Many of the electrochemical detection methods indicated as preferred are also carried out in this potential range. Particularly when very small amounts of a test substance are to be detected, even a comparatively small number of copper atoms can lead to a corruption or undesired influencing of the test signal.

The inventors' experiments have now shown that simpler measures are not sufficient to reduce the interference of the base metal core to the required low proportion. For example, it has proven to be inadequate to first extensively apply a nickel barrier layer and a gold layer to a copper film applied to the support plate and to structure this layer structure into a conductive pattern, since this does not result in a continuous diffusion barrier layer. In this procedure, copper atoms come into contact with the electrolyte solution through the inadequately protected lateral surfaces of the conductor paths.

Moreover, electrochemical detection offers a number of additional advantages that come to bear only when the parasitic, electrochemical influence of the base metal is reduced or completely eliminated by the diffusion barrier layer. These include, for example, the significantly higher sensitivity of the electrochemical read-out method compared to traditional methods due to the direct bonding of the catcher molecules to the subsequent electronics. In this way, the required evaluation time can also be greatly reduced. Also, the comparatively simple preparation results in a reduction of the overall time needed for a measurement. Unlike in traditional methods, the substance to be examined need not be modified by a special marker, or be brought to a detectable amount of substance through erroneous amplifications (multiplicative method).

According to a preferred embodiment, the metal core of the substrate according to the present invention comprises copper, tungsten and/or aluminum. In particular, the metal core can advantageously be formed of copper.

In an advantageous development of the present invention, the diffusion barrier layer comprises an interlayer made of nickel, titanium and/or platinum disposed between the metal core and the external gold layer. Such an interlayer effectively prevents the diffusion of atoms from the base metal core into the electrolyte solution and thus facilitates extremely sensitive electrochemical detection methods.

The interlayer expediently exhibits a thickness of about 2 μm to about 10 μm, preferably of about 3 μm to about 8 μm, particularly preferably of about 4 μm to about 6 μm.

According to a further advantageous embodiment of the present invention, the diffusion barrier layer comprises a lacquer layer applied to the gold layer.

It can likewise be provided that the diffusion barrier layer comprises, disposed on the metal core, a gold layer whose pores are substantially dosed by the incipient melting of a surface region of the gold layer, so that the migration of atoms from the metal core is practically prevented.

It is understood that the diffusion barrier layer can also be formed by a combination of multiple of the described measures. For example, the diffusion barrier layer can be formed only in sub-regions by a lacquer layer applied to the gold layer. In regions without an applied lacquer layer, such as the test sites, the gold layer can be incipiently melted by laser bombardment so that the gold layer itself forms a diffusion barrier layer in these regions.

It has proven to be particularly advantageous when the gold layer in the cited embodiments exhibits a thickness of about 0.15 μm to about 10 μm, preferably of about 1 μm to about 5 μm, particularly preferably of about 2 μm to about 3 μm.

In another embodiment of the present invention, the diffusion barrier layer is formed by a gold layer that is disposed on the metal core and whose thickness is chosen to be so large that it prevents direct contact of the electrolyte solution with the metal core.

The insulating support plate is expediently a single-sided rigid support plate, a double-sided rigid support plate or a rigid multilayer support plate. Alternatively, the insulating support plate can be a single-sided or double-sided flexible support plate, particularly made of a polyimide film, or a rigid-flexible support plate. It is advantageously composed of a base material selected from the group: BT (bismaleimide triazine resin with silica glass), CE (cyanate ester with silica glass), CEM1 (hard paper core with FR4 outer layers), CEM3 (fiberglass mat core with FR4 outer layers), FR2 (phenolic resin paper), FR3 (hard paper), FR4 (epoxide woven glass fabric), FR5 (epoxide woven glass fabric with a cross-linked resin system), PD (polyimide resin with aramide reinforcement), PTFE (polytetrafluoroethylene with glass or ceramic), CHn (highly cross-linked hydrocarbons with ceramic) and glass.

According to a further preferred embodiment of the present invention, the insulating support plate is formed by a semiconductor plate or a semiconductor plate provided with a support plate insulation layer. For example, the insulating support plate of the electrical substrate can advantageously be formed by a silicon plate provided with a SiNₓ insulation layer.

The conductor paths of the electrical substrate exhibit, in a preferred embodiment of the present invention, a width of 50 μm to 250 μm, especially of 80 μm to 200 μm.

If the conductor paths are formed on a semiconductor substrate, such as the cited SiNₓ-coated Si plate, they can also be formed considerably more narrowly, in line with traditional semiconductor technology processes, and exhibit a width of a few μm or even less than a micrometer. If the conductor paths are formed to be very narrow, they advantageously exhibit widenings in the region of the test sites to provide a sufficiently large surface for receiving biomolecules.

Furthermore, according to the present invention, it can advantageously be provided that an insulation layer is applied to the external gold layer in sub-regions. In particular, the insulation layer can advantageously be formed by a thermally and/or optically curable, structurable lacquer. In an expedient embodiment, the insulation layer is formed by a parylene layer.

According to the present invention, the insulation layer preferably exhibits a thickness of about 1 μm to about 30 μm, particularly preferably of about 5 μm to about 20 μm. The insulation layer expediently exhibits on a portion of the conductor paths voids reaching to the underlying gold layer that form test sites for the application of the biomolecules.

According to an advantageous development of the present invention, the conductive pattern includes one or more vias that exhibit a metal core made of a highly conductive base metal, and a gold layer surrounding the metal core, disposed at their circumferential edge surface. The vias are continuously provided with a diffusion barrier layer that prevents direct contact of the electrolyte solution with the metal core during the electrochemical detection method.

In this embodiment, the metal core of the vias is preferably formed of tungsten or aluminum. The diffusion barrier layer is expediently formed by an interlayer made of nickel, titanium and/or platinum disposed between the metal core of the vias and the external gold layer.

The thickness of the interlayer of the vias is advantageously about 0.01 μm to about 1 μm, preferably about 0.05 μm to about 0.5 μm, particularly preferably about 0.1 μm to about 0.2 μm. The gold layer of the vias advantageously exhibits a thickness of about 0.05 μm to about 0.75 μm, preferably of about 0.15 μm to about 0.5 μm, particularly preferably of about 0.3 μm.

The present invention also comprises the use of an electrical substrate of the described kind in an electrochemical detection method selected from the group: chronoamperometry (CA), chronocoulometry (CC), linear sweep voltammetry (LSV), cyclic voltammetry (CSV), AC voltammetry, voltammetry techniques with various pulse shapes, especially square wave voltammetry (SWV), differential pulse voltammetry (DPV), or normal pulse voltammetry (NPV), AC or DC impedance spectroscopy, chronopotentiometry and cyclic chronopotentiometry.

Further advantageous embodiments, features and details of the present invention are evident from the dependent claims, the description of the exemplary embodiments and the drawings.

### BRIEF DESCRIPTION OF THE DRAWINGS

The invention is intended to be explained in greater detail below by reference to exemplary embodiments in conjunction with the drawings. Only the elements that are essential to understanding the invention are depicted. Shown are

FIG. 1 a cutout of an electrical substrate according to an exemplary embodiment of the present invention, in a schematic diagram;

FIG. 2 a section through the electrical substrate of FIG. 1 along the line A-A; and

FIG. 3 a section as in FIG. 2 through an electrical substrate according to another exemplary embodiment of the present invention.

### MANNER OF EXECUTING THE INVENTION

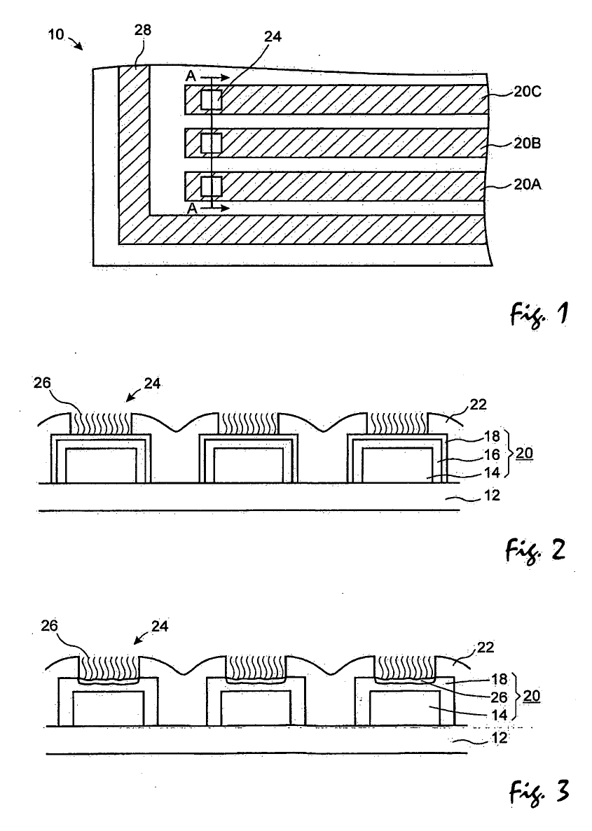

With reference to the schematic illustrations in FIGS. 1 and 2, 10 designates an electrical substrate that is employed as a carrier of biomolecules in a method for electrochemical detection in an electrolyte solution, as described for example in publication WO 00/42217.

The electrical substrate 10 comprises an insulating support plate 12 made of the epoxide woven glass fabric FR4, on which is disposed a conductive pattern having a plurality of, in the exemplary embodiment fifty, parallel conductor paths. In the cutout in FIG. 1, of the plurality of conductor paths, only a portion of the counterelectrode 28 and three of forty-eight parallel working electrodes is shown, designated 20A to 20C. The forty-eight parallel working electrodes each exhibit, as shown by way of example for working electrodes 20A to 20C, a substantially rectangular test site 24, to which biomolecules 26 are applied for the execution of an electrochemical detection method.

FIG. 2 shows a section along line A-A of FIG. 1, through the conductor paths 20A to 20C. Each of the conductor paths 20 is composed of a copper core 14 that is continuously coated by a nickel barrier layer 16 and a gold layer 18. In the exemplary embodiment, the copper core 14 has a thickness of about 28 μm. It constitutes an economical and highly conductive main component of the conductor paths 20.

To facilitate highly precise measurements during electrochemical detection in an aqueous medium, the copper cores 14 are continuously coated with the about 2 μm thick gold layer 18. Between the copper core 14 and the gold layer 18 is disposed in each case, as a diffusion barrier, an about 6 μm thick, continuous nickel layer 16.

The entire conductive pattern is coated with a 15 μm to 20 μm thick insulation layer 22, in the exemplary embodiment made of a structurable, optically curable lacquer. Into this insulation layer 22 are introduced rectangular voids 24, for example by laser bombardment of the insulation layer 22 with high-energy impulses of an excimer laser. The voids 24 form the test sites for receiving the biomolecules 26.

The conductor paths 20 of the exemplary embodiment of FIGS. 1 and 2 are about 100 μm wide and are disposed on the support plate 12 with spacing of about 200 μm (center-center). The quadratic test sites 24 exhibit an extension of about 60 μm×60 μm. The working electrodes 20A-20C, the counterelectrode 28 and a reference electrode that is likewise provided, if appropriate, are each joined with connecting contact surfaces, which are not shown, of the electrical substrate 10 for contact.

To execute an electrochemical detection, in chronocoulometry, for example, charge-time curves are recorded, as described in detail in the publication WO 00/42217. For this, the test sites 24 of the forty-eight working electrodes 20A, 20B, 20C, . . . , are selectively loaded with probe biomolecules, for example 20-nucleotide-ligate-oligonucleotides. The test sites 24 are then brought into contact with a signal-oligonucleotide solution, for example a 12-nucleotide-signal-nucleic-acid-oligomer-ligand, and measured after a predetermined incubation period. Here, the signal-nucleic-acid-oligomer-ligands bear one or more redox labels and are complementary to a surface-near region of the ligate-oligonucleotide, so that an association can occur between the ligate-oligonucleotide and the redox-labeled signal-nucleic-acid-oligomer-complexing-agent.

Then, by means of a potentiostat, the working electrodes are set, individually or in groups, to a first potential at which little to no electrolysis (electrochemical change in the redox state) of the redox label can occur. For example, in ferrocene-modified ligate-oligonucleotides, the working electrode is set in each case to a potential of about 100 mV against the reference electrode, in the exemplary embodiment (Ag/AgCl (KCl)).

Thereafter, the working electrode(s) is/are set, by a potential jump, to a second, higher potential at which electrolysis of the redox label occurs in the diffusion-limited borderline case. For ferrocene-modified-ss-nucleic-acid-oligomer-complexing-agents, the working electrode is set to about 500 mV against Ag/AgCl (KCl). The transfered charges are recorded as a test signal as a function of time.

This test signal in chronocoulometry, the transferred charge Q as a function of time t, is made up of three components: a diffusive portion that is induced by the dissolved redoxactive components in the volume phase and exhibits a t^{1/2} dependence, a first instantaneous portion that results from the charge redistribution in the double layer at the electrode surface, and a second instantaneous portion that is effected by the transformation of redoxactive components that are immobilized at the electrode surface.

After the first measurement, the sample solution is added that should or can contain the ligand nucleic acid oligomer (target), which exhibits a nucleotide sequence that, in one region, is complementary to the 20-nucleotide of the ligate-oligonucleotide. Following hybridization of the target to the ligate-oligonucleotide, and thus following partial displacement of the signal-nucleic-acid-oligomer-ligands, a second electrochemical measurement is taken. The change in the instantaneous charge signal is proportional to the number of displaced signal-oligonucleotide-ligands and is thus proportional to the number of target-oligonucleotides present in the test solution.

A section through an electrical substrate 10 according to another exemplary embodiment of the present invention is illustrated in FIG. 3. As in the exemplary embodiment of FIG. 2, each of the conductor paths 20 includes a copper core 14. In contrast to the above-described embodiment, however, the copper core 14 is coated directly with an about 7 μm thick gold layer 18, and the conductive pattern is covered with a 15 μm thick parylene lacquer layer 22.

To define test sites 24, for each conductor path 20, a void is introduced into the lacquer layer 22 by excimer laser bombardment. Here, the laser energy and the number of laser pulses are selected so that, after the lacquer layer 22 is removed, the gold layer 18 that lies under the lacquer layer begins to melt in a surface region 26. As a result, the surface pores of the gold layer 18 are closed in the region of the test sites 24, so that the gold layer 18 there forms a barrier layer that is impermeable for diffussing copper atoms. In the other regions, the lacquer layer 22 prevents contact of the copper atoms with the electrolyte solution.

In a further exemplary embodiment of the present invention, every conductor path 20 includes an about 2 μm thick metal core made of tungsten. Here, the tungsten core is continuously covered with a diffusion barrier layer, formed in each case of 2 μm thick layers of titanium and platinum. To this diffusion barrier layer is continuously applied an about 2 μm thick gold layer on which, in the above-described manner, an array of test sites is defined for receiving biomolecules. Also an electrical substrate designed in this way allows the execution of highly sensitive electrochemical detection methods.

According to yet another exemplary embodiment of the present invention, a silicon support plate coated with SiNₓ includes a plurality of circular vias in which a tungsten core circulating at the edge of the vias is covered with an about 0.1 μm thick titanium layer and an about 0.1 μm thick platinum layer. To the barrier layer formed in this way is applied a 0.3 μm thick gold layer. In this way, a semiconductor substrate is created that is suitable for highly sensitive electrochemical detection methods.

While the present invention has been shown and described with reference to preferred exemplary embodiments, it will be understood by a person skilled in the art that changes can be made in the design and details without deviating from the spirit and scope of the present invention. For example, instead of the tungsten core of the vias, an aluminum core can also be used. Also, the support plate insulation layer can be formed of silicon oxide or oxynitride compounds instead of silicon nitride. Accordingly, the disclosure of the present invention is not intended to be limiting. Instead, the disclosure of the present invention is intended to exemplify the scope of the invention that is set out in the following claims.

1-26. (canceled)

27. An electrical substrate for use as a carrier of biomolecules in a method for electrochemical detection in an electrolyte solution, comprising:
an insulating support plate that bears a conductive pattern having conductor paths and connecting contact surfaces, and having disposed on the conductor paths test sites for the application of biomolecules;
wherein the conductor paths comprise a metal core made of a highly conductive base metal and a gold layer surrounding the metal core, and the conductor paths are continuously provided with a diffusion barrier layer that prevents direct contact of the electrolyte solution with the metal core during the electrochemical detection method.

28. The electrical substrate according to claim 27, wherein the metal core comprises copper, tungsten, or aluminum.

29. The electrical substrate according to claim 27, wherein the metal core is formed of copper.

30. The electrical substrate according to claim 27, wherein the diffusion barrier layer comprises an interlayer made of nickel, titanium or platinum disposed between the metal core and the external gold layer.

31. The electrical substrate according to claim 30, wherein the interlayer exhibits a thickness of about 2 μm to about 10 μm.

32. The electrical substrate according to claim 27, characterized in that the diffusion barrier layer comprises a lacquer layer applied to the gold layer (18).

33. The electrical substrate according to claim 27, characterized in that the diffusion barrier layer comprises, disposed on the metal core, a gold layer (18) whose pores are substantially closed by the incipient melting of a surface region (26) of the gold layer (18).

34. The electrical substrate according to claim 27, wherein the gold layer (18) exhibits a thickness of about 0.15 μm to about 10 μm.

35. The electrical substrate according to claim 27, characterized in that the diffusion barrier layer is formed by a gold layer that is disposed on the metal core and whose thickness is chosen to be so large that it prevents direct contact of the electrolyte solution with the metal core.

36. The electrical substrate according claim 27, wherein the insulating support plate is a single-sided rigid support plate, a double-sided rigid support plate or a rigid multilayer support plate.

37. The electrical substrate according to claim 27, characterized in that the insulating support plate is a single-sided or double-sided flexible support plate, wherein the single-sided or double-sided support plate is manufactured from a polyimide film or a rigid-flexible support plate.

38. The electrical substrate according claim 27 wherein, the insulating support plate is composed of a base material selected from the group comprising: bismaleimide triazine resin with silica glass, cyanate ester with silica glass, hard paper core with epoxide woven glass fabric outer layers, fiberglass mat core with epoxide woven glass fabric outer layers, phenolic resin paper, hard paper, epoxide woven glass fabric, epoxide woven glass fabric with a cross-linked resin system, polyimide resin with aramide reinforcement, polytetrafluoroethylene with glass or ceramic, highly cross-linked hydrocarbons with ceramic and glass.

39. The electrical substrate according to claim 27 wherein the insulating support plate is formed by a semiconductor plate or a semiconductor plate provided with a support plate insulation layer.

40. The electrical substrate according to claim 39, wherein the insulating support plate comprises a silicon plate provided with a SiNₓ insulating layer.

41. The electrical substrate according to claim 27, characterized in that the conductor paths exhibit a width of about 50 μm to about 250 μm.

42. The electrical substrate according to claim 27, wherein an insulation layer is applied to the gold layer in sub-regions.

43. The electrical substrate according to claim 42, wherein the insulation layer is formed by a thermally curable lacquer, optically curable lacquer, an optically and thermally curable lacquer or a structurable lacquer.

44. The electrical substrate according to claim 42, wherein the insulation layer is formed by a parylene layer.

45. The electrical substrate according to claim 42 wherein the insulation layer exhibits a thickness of about 1 μm to about 30 μm.

46. The electrical substrate according to claim 42 wherein the insulation layer on a portion of the conductor paths exhibits voids that reach to the underlying gold layer and that form test sites for the application of the biomolecules.

47. The electrical substrate according to claim 42 characterized in that the conductive pattern includes one or more vias that exhibit, disposed at their circumferential edge surface, a metal core made of a highly conductive base metal, and a gold layer surrounding the metal core, and the vias being continuously provided with a diffusion barrier layer that prevents direct contact of the electrolyte solution with the metal core during the electrochemical detection method.

48. The electrical substrate according to claim 47, wherein the metal core of the vias comprises tungsten or aluminum.

49. The electrical substrate according to claim 47 wherein the diffusion barrier layer is formed by an interlayer comprising nickel, titanium, or platinum disposed between the metal core of the vias and the external gold layer.

50. The electrical substrate according to claim 49 wherein the interlayer of the vias exhibits a thickness of about 0.01 μm to about 1 μm.

51. The electrical substrate according to claim 47 wherein the gold layer of the vias has a thickness of about 0.05 μm to about 0.75 μm.
